(19) United States
(12) Patent Application Publication
(10) Pub. No.: US 2016/0195585 A1
(43) Pub. Date: Jul. 7, 2016

(54) SYSTEMS AND METHODS FOR DETERMINING A REMAINING BATTERY CAPACITY OF A BATTERY DEVICE

(71) Applicant: MediaTek Inc., Hsin-Chu (TW)

(72) Inventors: Jui-Chi WU, Taichung City (TW); Yong-Sheng LO, Taichung City (TW)

(21) Appl. No.: 14/980,506

(22) Filed: Dec. 28, 2015

Related U.S. Application Data
(62) Division of application No. 13/605,857, filed on Sep. 6, 2012, now abandoned.
(60) Provisional application No. 61/668,618, filed on Jul. 6, 2012.
(60) Provisional application No. 61/535,195, filed on Sep. 15, 2011.

(51) Int. Cl. G01R 31/36

(52) U.S. Cl. CPC G01R 31/3634; G01R 31/3662; G01R 31/3675

(57) ABSTRACT

A system for determining a remaining battery capacity includes a detection circuitry and a controller. The detection circuitry is coupled to a battery device for detecting an open circuit and a closed circuit voltage of the battery device. The controller is coupled to the detection circuitry, calculates an amount of current drawn out from the battery device based on values of the open circuit voltage and the closed circuit voltage and a resistance of the internal resistor, calculates a present depth of discharge based on the amount of current, and determines the remaining battery capacity of the battery device according to the present depth of discharge.

### CROSS REFERENCE TO RELATED APPLICATIONS

This application is a Divisional of pending U.S. patent Ser. No. 13/605,857, filed on Sep. 6, 2012, which claims the benefit of U.S. Provisional Application No. 61/535,195 filed 2011 Sep. 15, entitled “Gas Gauge patent” and U.S. Provisional Application No. 61/668,618 filed 2012 Jul. 6, entitled “Fuel Gauge Zero Cost patent”. The entire contents of which are hereby incorporated by reference.

### BACKGROUND OF THE INVENTION

1. Field of the Invention

The invention relates to circuits and methods for determining a remaining battery capacity.

2. Description of the Related Art

Modern handheld electronic devices, such as cellular phones, notebooks, tablet computers, GPS receivers, and the like, are powered by battery devices for being easy to carry. In this regard, precise determination of the remaining battery capacity and sustainability of the battery device is an important issue.

Conventionally, the remaining battery capacity is determined by measuring the cross voltage of the battery device and consulting a table of voltage versus battery capacity so as to determine the remaining battery capacity. However, the conventional determination may be inaccurate because the cross voltage of the battery device may be unstable and may vary along with different system loadings. For example, when the system loading is heavy, a huge amount of current is drawn from the battery device, causing the cross voltage of the battery device to drop dramatically. On the other hand, when the system loading is light, only a small amount of current is drawn from the battery device, causing the cross voltage of the battery device to drop only slightly.

If the cross voltage of the battery device is measured during the period of heavy system loading, the current battery capacity may be wrongfully determined to be much less than its actual remaining battery capacity since the heavy system loading may only occur for a short period of time and the amount of discharge is not as huge as determined.

Therefore, circuits and methods for precisely determining a remaining battery capacity are desired.

### BRIEF SUMMARY OF THE INVENTION

Systems and methods for determining a remaining battery capacity of a battery device are provided. An exemplary embodiment of the system comprises a detection circuitry and a controller. The detection circuitry is coupled to a battery device at a detection node for detecting a closed circuit voltage of the battery device. The controller is coupled to the detection circuitry, derives an amount of current drawn out from the battery device based on the closed circuit voltage, calculates an open circuit voltage of the battery device based on the current, and determines the remaining battery capacity of the battery device based on the open circuit voltage.

An exemplary embodiment of a method for determining a remaining battery capacity of a battery device comprises: (a) detecting a closed circuit voltage of the battery device; (b) detecting an amount of current drawn out from the battery device via an external resistor coupled to the battery device; (c) deriving a resistance of an internal resistor comprised in the battery device; (d) calculating a voltage drop caused by the external resistor and the internal resistor based on the amount of current, a resistance of the external resistor and the resistance of the internal resistor; (e) calculating a value of the open circuit voltage using the voltage drop; and (f) determining the remaining battery capacity of the battery device according to the value of the open circuit voltage.

Another exemplary embodiment of a method for determining a remaining battery capacity of a battery device comprises: (a) obtaining an open circuit voltage of the battery device; (b) deriving a resistance of an internal resistor comprised in the battery device; (c) detecting a closed circuit voltage of the battery device; (d) calculating an amount of current drawn out from the battery device based on a value of the open circuit voltage, a value of the closed circuit voltage and the resistance of the internal resistor; (e) calculating a present depth of discharge based on the amount of current; and (f) determining the remaining battery capacity of the battery device according to the present depth of discharge.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram showing a system for determining a remaining battery capacity according to a first embodiment of the invention;

FIG. 2 is a schematic diagram showing a curve of the open circuit voltage versus the depth of discharge and a curve of the closed circuit voltage versus the depth of discharge (DOD) according to an embodiment of the invention;

FIG. 3 is a diagram showing an equivalent circuit of a battery device according to an embodiment of the invention;

FIG. 4 is a schematic diagram showing a concept of repeatedly updating the value of the open circuit voltage to obtain a convergent value of the open circuit voltage according to the first embodiment of the invention;

FIG. 5 is a schematic diagram showing a concept of repeatedly updating the resistance of the internal resistor R_{INT} of the battery device according to the first embodiment of the invention;

FIG. 6 is a flow chart showing a method for determining a remaining battery capacity of a battery device according to the first embodiment of the invention;

FIG. 7 is a block diagram showing a system for determining a remaining battery capacity according to a second embodiment of the invention;

FIG. 8 is a flow chart showing a method for determining a remaining battery capacity of a battery device according to the second embodiment of the invention; and

FIG. 9 is a schematic diagram showing a curve of the maximum battery capacity Qmax versus a number of charge/discharge cycles.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

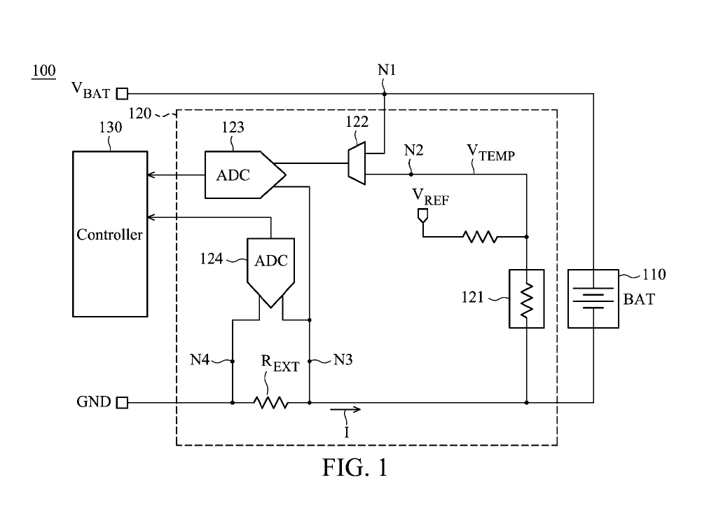

FIG. 1 is a block diagram showing a system for determining a remaining battery capacity of a battery device according to a first embodiment of the invention. According to the first embodiment of the invention, the system 100 may comprise a detection circuitry 120 coupled to a battery device 110 and a controller 130 coupled to the detection circuitry 120. The detection circuitry 120 is coupled to the battery device 110 at a detection node N1 for detecting a battery voltage V_{BAT} of the battery device 110. The controller 130 receives information regarding the battery voltage V_{BAT} of the battery device 110 from the detection circuitry 120, derives an amount of current drawn out from the battery device 110 based on the closed circuit voltage, calculates an open circuit voltage (OCV) of the battery device 110 based on the derived current and determines the remaining battery capacity of the battery device 110 based on the open circuit voltage (OCV).

Generally, when there is zero or nearly zero current drawn out from the battery device 110, the battery voltage V_{BAT} detected by the detection circuitry 120 may be referred to as the open circuit voltage (OCV) since the two terminals of the battery device 110 may be regarded as disconnected from any circuit and/or there is no-load connected to the battery device 110. Alternatively, when there is some current drawn out from the battery device 110, the battery voltage V_{BAT} detected by the detection circuitry 120 may be referred to as a closed circuit voltage (CCV).

According to the first embodiment of the invention, the detection circuitry 120 may comprise a temperature sensing device 121, a multiplexer 122, an external resistor R_{EXT} and two analog to digital converters (ADC) 123 and 124. The temperature sensing device 121 is coupled to the battery device 110 for sensing a temperature of the battery device 110 and generates a sensed voltage V_{TEMP} reflecting the temperature of the battery device 110 at a sensing node N2. According to an embodiment of the invention, the temperature sensing device 121 may be a negative temperature coefficient (NTC) device, such as a thermistor. The temperature sensing device 121 may be coupled to a reference voltage source for receiving a reference voltage V_{REF} therefrom.

The multiplexer 122 is coupled to the sensing node N2 and the detection node N1 for receiving the sensed voltage V_{TEMP} and the battery voltage V_{BAT}, respectively, and multiplexes the sensed voltage V_{TEMP} and the battery voltage V_{BAT} so as to selectively output one of the sensed voltage V_{TEMP} and the battery voltage V_{BAT} to the following ADC 123 in response to a switch command. According to an embodiment of the invention, the switch command may be issued by the controller 130 for selecting a desired voltage to be received. The ADC 123 is coupled to the multiplexer 122 for receiving and analog to digital converting one of the sensed voltage V_{TEMP} and the battery voltage V_{BAT} outputted by the multiplexer 122, and outputs the converted result of the one of the sensed voltage V_{TEMP} and the battery voltage V_{BAT} to the controller 130.

The ADC 124 is coupled to the external resistor R_{EXT}, which is configured for sensing an amount of current drawn out from the battery device 110, for detecting the voltage difference between two terminals of the external resistor R_{EXT}, such as a voltage difference between a voltage V_{A} at the node N3 and a voltage V_{B} the node N4. The ADC 124 analog to digital converts the voltage difference and outputs the converted results of the voltage difference to the controller 130.

According to the first embodiment of the invention, the controller 130 may derive the amount of current I drawn out from the battery device 110 based on the voltage difference between the voltages V_{A} and V_{B} detected by the ADC 124. For example, the controller 130 can estimate the value of current I according to the voltage difference and a predetermined external resistor R_{EXT}. That is, the value of current I may be derived as indicated below:

I=(V_{A}−V_{B})/R_{E} Eq. (1)

where R_{E} is the resistance of the external resistor R_{EXT}. After obtaining the current I, the controller 130 may further derive the open circuit voltage V_{OCV} based on the current I and the battery voltage V_{BAT} detected by the detection circuitry 120.

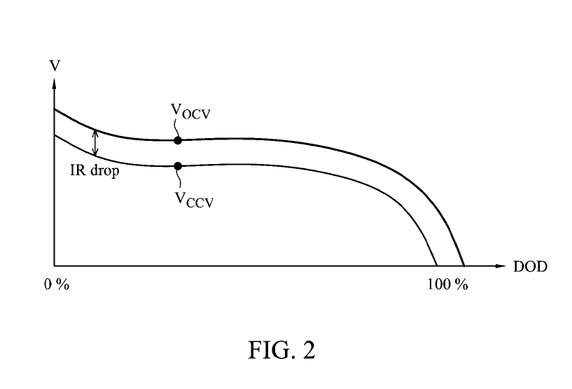

FIG. 2 is a schematic diagram showing a curve of the open circuit voltage V_{OCV} versus the depth of discharge and a curve of the closed circuit voltage V_{CCV} versus the depth of discharge (DOD) according to an embodiment of the invention. In the embodiments of the invention, the depth of discharge (DOD) is represented by percentage, which is derived by dividing the depth of discharge into a maximum battery capacity of the battery device. As shown in FIG. 2, there is a voltage drop (labeled as the “IR drop”) exists between the open circuit voltage V_{OCV} and the closed circuit voltage V_{CCV}. Therefore, the controller 130 may compensate for the amount of voltage drop at the closed circuit voltage V_{CCV} so as to derive the open circuit voltage V_{OCV}.

According to the first embodiment of the invention, when there is no information regarding the open circuit voltage V_{OCV} of the battery device 110, the controller 130 may initially set a currently detected battery voltage V_{BAT}, which may be a closed circuit voltage V_{CCV}, as an initial value of the open circuit voltage V_{OCV}. Next, the controller 130 may repeatedly update the value of the open circuit voltage V_{OCV} by compensating for the voltage drop at the value of the previously obtained open circuit voltage V_{OCV}, where the voltage drop may be contributed by the current flowing through the external resistor R_{EXT} and an internal resistor R_{INT} of the battery device.

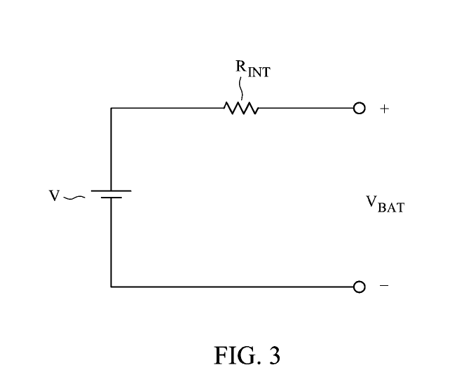

FIG. 3 is a diagram showing an equivalent circuit of a battery device according to an embodiment of the invention. The equivalent circuit of a battery device may comprise a voltage source V and an internal resistor R_{INT}. A voltage provided by the voltage source V may be regarded as the open circuit voltage V_{OCV} of the battery device. According to the first embodiment of the invention, the controller 130 may obtain information regarding the detected battery voltage V_{BAT} from the detection circuitry 120, and set the detected battery voltage V_{BAT} as an initial value V₁ of the open circuit voltage V_{OCV}. Next, the controller 130 may update the value V₁ of the open circuit voltage V_{OCV} as indicated below:

V₂=V₁+I×[R₁+R_{E}] Eq. (2)

where V₂ is an updated value of the open circuit voltage V_{OCV}, I is the current measured via the external resistor R_{EXT} as shown in Eq. (1), R₁ is an initial value of the resistance of the internal resistor R_{INT} of the battery device 110 as shown in FIG. 3, and R_{E} is the resistance of the external resistor R_{EXT}.

According to an embodiment of the invention, the controller 130 may obtain a resistance of the internal resistor R_{INT} of the battery device 110 by looking up one or several predefined tables. In the embodiment of the invention, the tables may be predefined when manufacturing the system 100 and may be stored in an internal or external memory (not shown) of the controller 130. The predefined tables may comprise a first table of the open circuit voltage versus the depth of discharge (DOD) of the battery device and a second table of the resistance of the internal resistor R_{INT} versus the depth of discharge (DOD) of the battery device. Note that the remaining battery capacity (which can also be represented by percentage) may be an alternative choice to replace the depth of discharge when defining the tables since a sum of the remaining battery capacity and the depth of discharge is a fixed number (for example, 1 or 100% when both the depth of discharge and the remaining battery capacity are represented by percentage).

In addition, since the battery characteristic may vary with different environment temperatures, the tables may be predefined under different temperatures when manufacturing the system 100 and may be stored in an internal or external memory (not shown) of the controller 130. The controller 130 may select a suitable first table and a suitable second table from the predefined tables based on the sensed voltage V_{TEMP} that reflects the temperature of the battery device.

Therefore, in the first embodiment of the invention, before deriving the open circuit voltage, the controller 130 may initially set a currently detected battery voltage V_{BAT}, which may be a closed circuit voltage V_{CCV}, as an initial value V₁ of the open circuit voltage V_{OCV}, and look up the first table based on the initial value V₁ to obtain a derived depth of discharge (DOD) D₁ of the battery device. The controller 130 may further look up the second table based on the derived depth of discharge (DOD) D₁ to obtain an initial value R₁ of the resistance of the internal resistor R_{INT}. After obtaining the initial value R₁ of the resistance of the internal resistor R_{INT}, the controller 130 may update the value V₁ as shown in Eq. (2).

Next, the controller 130 may further look up the first table based on the updated value V₂ to obtain an updated value D₂ of the derived depth of discharge (DOD) of the battery device, and look up the second table based on the updated value D₂ of the derived depth of discharge (DOD) to obtain an updated value R₂ of the resistance of the internal resistor R_{INT}. Next, the controller 130 may further obtain another updated the value V₃ of the open circuit voltage V_{OCV} as indicated below:

V₃=V₂+I×[R₂+R_{E}] Eq. (3)

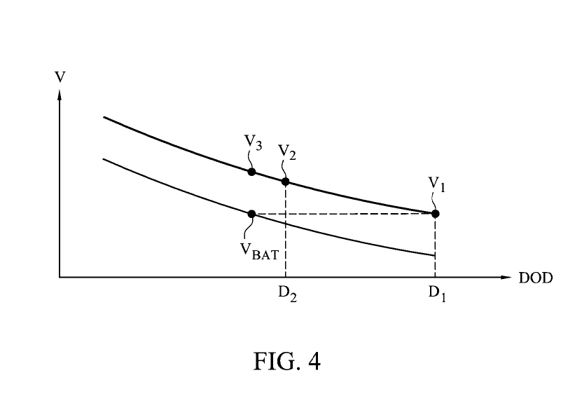

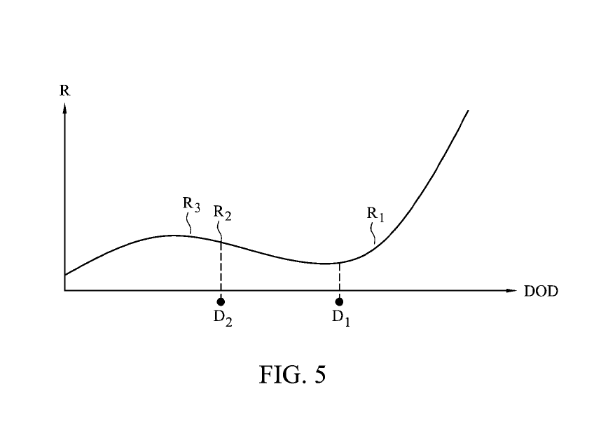

According to an embodiment of the invention, the controller 130 may further repeatedly update the resistant of the internal resistor R_{INT}, the amount of the voltage drop and the value of the open circuit voltage for a predetermined number of times to obtain a convergent value of the open circuit voltage. FIG. 4 is a schematic diagram showing a concept of repeatedly updating the value of the open circuit voltage to obtain a convergent value of the open circuit voltage according to the first embodiment of the invention, and FIG. 5 is a schematic diagram showing a concept of repeatedly updating the resistance of the internal resistor R_{INT} of the battery device according to the first embodiment of the invention. In a preferred embodiment of the invention, the value of the open circuit voltage may converge after three or four times of updates.

Finally, the controller 130 may look up the first table based on the convergent value of the open circuit voltage to obtain a final value D_{f} of the derived depth of discharge (DOD) and determine the remaining battery capacity as indicated below:

Remaining_battery_capacity=1−D_{f} Eq. (4)

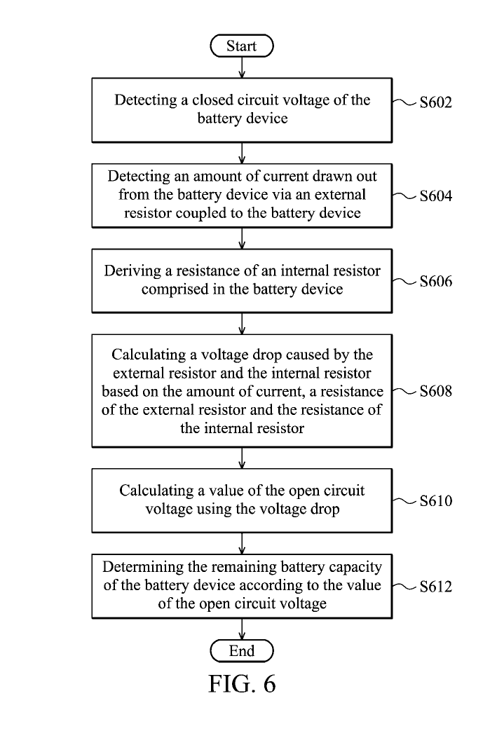

FIG. 6 is a flow chart showing a method for determining a remaining battery capacity of a battery device according to the first embodiment of the invention. To begin, a closed circuit voltage of the battery device may be detected (Step S602). In the embodiments of the invention, the battery voltage of the battery device may be detected anytime. For example, when the system 100 as shown in FIG. 1 is comprised in an electronic device powered by the battery device 110, the battery voltage may be detected anytime when the electronic device is functioning. Since the battery voltage is detected when the electronic device is functioning, the detected battery voltage may be regarded as the closed circuit voltage V_{CCV} of the battery device 110.

Next, an amount of current drawn out from the battery device may be detected via an external resistor coupled to the battery device as shown in FIG. 1 (Step S604). Next, a resistance of an internal resistor comprised in the battery device may be derived (Step S606). As illustrated above, the resistance of the internal resistor may be derived by looking up the first and second tables. Note that in some embodiments of the invention, the second table may be simplified by only comprising several values of the resistance versus several predefined values of the depth of discharge (DOD). Therefore, the resistance of the internal resistor may be derived simply by performing interpolation between two or more closest values. Note further that in some other embodiments of the invention, the second table may be omitted and the resistance of the internal resistor may be set as a fixed value regardless of the depth of discharge (DOD). Therefore, the resistance of the internal resistor may be derived simply based on the sensed temperature of the battery device. Note further that in still some other embodiments of the invention, the second table may be omitted and the resistance of the internal resistor may be set as a fixed value regardless of the depth of discharge (DOD) and the temperature. Therefore, the resistance of the internal resistor may be derived by directly obtaining the fixed value as the resistance of the internal resistor. Note further that in still some other embodiments of the invention, the resistance of the internal resistor or the resistance of the internal resistor in the second table may be updated anytime based on a current status of the electronic device. For example, the resistance of the internal resistor may be updated according to a charge/discharge voltage rise/drop and a charge/discharge current measured in a charge/discharge procedure of the battery device 110.

Next, a voltage drop caused by the external resistor and the internal may be calculated based on the amount of current obtained in step S604, a resistance of the external resistor, which is a known value, and the resistance of the internal resistor obtained in step S606 (Step S608). Next, the value of the open circuit voltage may be calculated by using the voltage drop as shown in Eq. (2) (Step S610). Finally, the remaining battery capacity of the battery device may be determined according to the value of the open circuit voltage (Step S612).

Note that in some embodiments of the invention, before performing the step S612, the steps S606, S608 and S610 may be repeatedly performed for a predetermined number of times based a latest updated value of the open circuit voltage obtained in step S610 so as to obtain a convergent value of the open circuit voltage, which may be much closer to the actual open circuit voltage of the battery device. After obtaining the convergent value of the open circuit voltage, the remaining battery capacity of the battery device may be determined according to the convergent value of the open circuit voltage.

Note further that in still some embodiments of the invention, the controller 130 may further process a plurality of values of the remaining battery capacity of the battery device determined during a period of time to obtain an accurate value as the remaining battery capacity of the battery device. For example, the controller 130 may calculate an average among the values determined during the period of time as the accurate value, or may further filter out some values diverging from the others before calculating the average so that the determined remaining battery capacity may be a more stable result.

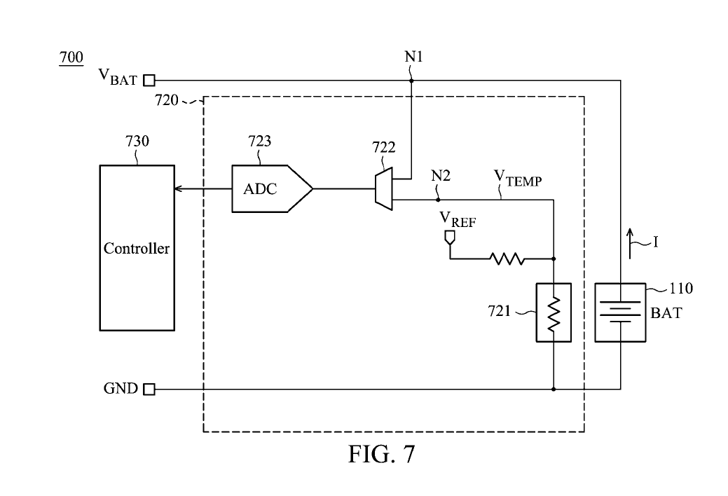

FIG. 7 is a block diagram showing a system for determining a remaining battery capacity according to a second embodiment of the invention. According to the second embodiment of the invention, the system 700 may comprise a detection circuitry 720 coupled to a battery device 110 and a controller 730 coupled to the detection circuitry 720. The detection circuitry 720 is coupled to the battery device 110 at a detection node N1 for detecting a battery voltage V_{BAT} of the battery device 110. The controller 730 receives information regarding the battery voltage V_{BAT} of the battery device 110 from the detection circuitry 720 to detect an open circuit voltage (OCV) and a closed circuit voltage (CCV) of the battery device 110, calculates an amount of current drawn out from the battery device 110 based on values of the open circuit voltage (OCV) and the closed circuit voltage (CCV) and a resistance of the internal resistor, calculates a present depth of discharge based on the amount of current, and determines the remaining battery capacity of the battery device 110 according to the present depth of discharge.

According to the second embodiment of the invention, the detection circuitry 720 may comprise a temperature sensing device 721, a multiplexer 722, and an analog to digital converters (ADC) 723. The temperature sensing device 721 is coupled to the battery device 110 for sensing a temperature of the battery device 110 and generates a sensed voltage V_{TEMP} reflecting the temperature of the battery device 110 at a sensing node N2. According to an embodiment of the invention, the temperature sensing device 721 may be a negative temperature coefficient (NTC) device, such as a thermistor. The temperature sensing device 721 may be coupled to a reference voltage source for receiving a reference voltage V_{REF} therefrom.

The multiplexer 722 is coupled to the sensing node N2 and the detection node N1 for receiving the sensed voltage V_{TEMP} and the battery voltage V_{BAT}, respectively, and multiplexes the sensed voltage V_{TEMP} and the battery voltage V_{BAT} so as to selectively output one of the sensed voltage V_{TEMP} and the battery voltage V_{BAT} to the following ADC 723 in response to a switch command. According to an embodiment of the invention, the switch command may be issued by the controller 730 for selecting a desired voltage to be received. The ADC 723 is coupled to the multiplexer 722 for receiving and analog to digital converting one of the sensed voltage V_{TEMP} and the battery voltage V_{BAT} outputted by the multiplexer 722, and outputs the converted result of the one of the sensed voltage V_{TEMP} and the battery voltage V_{BAT} to the controller 730.

Note that in the second embodiment of the invention, since there is no external resistor coupled to the battery device 110, the amount of current I drawn out from the battery device 110 is unable to be measured or detected by the detection circuitry 720. Therefore, in the second embodiment of the invention, the controller 730 may calculate the amount of current I drawn out from the battery device 110 based on the detected battery voltage V_{BAT} and the resistance of the internal resistor R_{INT} comprised in the battery device 110.

According to the second embodiment of the invention, the detection circuitry 720 may first detect an initial voltage of the battery device right at the moment when the system 700 (or an electronic device comprising the system 700 and powered by the battery device 110) is started up. Since there is no current or very small and near zero current drawn out from the battery device 110 before the system 700 is started up, the initial voltage of the battery device detected right at the moment when started up may be regarded as the open circuit voltage V_{OCV} of the battery device. The detection circuitry 720 may further detect the battery voltage of the battery device 110 after a predetermined period of time T, for example, 10 seconds. Since there is some current drawn out from the battery device 110 after the system 700 is started up, the battery voltage of the battery device detected after a predetermined period of time may be regarded as the closed circuit voltage V_{CCV} of the battery device.

After obtaining the open circuit voltage V_{OCV} and the closed circuit voltage V_{CCV} of the battery device 110, the controller 730 may derive the amount of current drawn out from the battery device 110 by dividing a difference between the open circuit voltage V_{OCV} and the closed circuit voltage V_{CCV} into a resistance of an internal resistor comprised in the battery device as indicated below:

I₁=(V_{OCV}−V_{CCV})/R₁ Eq. (5)

where I₁ is an initial value of the amount of current and R₁ is an initial value of the resistance an internal resistor of the battery device 110 as shown in FIG. 3.

According to an embodiment of the invention, the controller 730 may obtain the initial value R₁ of the resistance of the internal resistor R_{INT} of the battery device 110 by looking up several predefined tables. In the embodiment of the invention, the tables may be predefined when manufacturing the system 700 and may be stored in an internal or external memory (not shown) of the controller 730. The predefined tables may comprise a first table of the open circuit voltage versus the depth of discharge (DOD) of the battery device and a second table of the resistance of the internal resistor R_{INT} versus the depth of discharge (DOD) of the battery device. Note that the remaining battery capacity may be an alternative choice to replace the depth of discharge when defining the tables since a sum of the remaining battery capacity and the depth of discharge is a fixed number (for example, 1 when both the depth of discharge and the remaining battery capacity are represented by percentage).

In addition, since the battery characteristic may vary with different environment temperatures, the tables may be predefined under different temperatures when manufacturing the system 700 and may be stored in an internal or external memory (not shown) of the controller 730. The controller 730 may select a suitable first table and a suitable second table from the predefined tables based on the sensed voltage V_{TEMP} which is capable reflecting the temperature of the battery device.

Therefore, in the second embodiment of the invention, since the initial voltage of the battery device detected right at the moment when started up may be regarded as the open circuit voltage V_{OCV}, the controller 730 may look up the first table based on the initial voltage of the battery device to obtain a derived depth of discharge (DOD) D₁ of the battery device. The controller 730 may further look up the second table based on the derived depth of discharge (DOD) D₁ to obtain an initial value R₁ of the resistance of the internal resistor R_{INT}. After obtaining the initial value R₁ of the resistance of the internal resistor R_{INT}, the controller 730 may calculate the amount of current I as shown in Eq. (5).

After the deriving the amount of current I, the controller 730 may further calculate a present depth of discharge of the battery device based on the amount of current I as indicated below:

CAR₂=I₁×T+CAR₁ Eq. (6)

D₂=D₁+CAR₂/Qmax Eq. (7)

where D₁ is the initial depth of discharge obtained according to the open circuit voltage V_{OCV} that is detected right at the moment when started up, the CAR₁ is an initial amount of consumed battery capacity, which may be initially set to 0, the CAR₂ is an updated result of the amount of consumed battery capacity, T is the predetermined period of time T waited by the controller 730 and Qmax is a maximum battery capacity of the battery device. Note that the Qmax may be a known value when manufacturing the system 700 and may further be updated since the maximum battery capacity of the battery device may be decreased as the battery “age” increases or may be changed when the battery device is changed by an user (the methods of updating a value of the maximum battery capacity of the battery device will be further discussed in the following paragraphs).

After obtaining the present depth of discharge D₂ of the battery device, the controller 730 may determine the remaining battery capacity based on the present depth of discharge D₂ as indicated below:

Remaining_battery_capacity=1−D₂ Eq. (8)

Note that in some embodiments of the invention, for getting a more accurate estimation of the remaining battery capacity, the controller 730 may further update the value of the open circuit voltage V_{OCV} and the value of the resistance of the internal resistor R_{INT} by looking up the first and second tables based on the present depth of discharge D₂ derived as in Eq (7), so as to obtain an updated value V_{OCV2} of the open circuit voltage and an updated value R₂ of the resistance of the internal resistor R_{INT}. Next, the controller 730 may further wait for a predetermined period of time, for example, T and measure a current closed circuit voltage V_{CCV} of the battery device 110. Next, the controller 730 may further update the amount of current and the present depth of discharge of the battery device as following:

I₂=(V_{OCV2}−V_{CCV})/R₂ Eq. (9)

CAR₃=I₂×T+CAR₂ Eq. (10)

D₃=CAR₃/Qmax Eq. (11)

In some embodiments of the invention, the controller 730 may repeatedly measure a latest current closed circuit voltage V_{CCV} and update the value of the open circuit voltage, the resistance of the internal resistor R_{INT} and the amount of current for a predetermined number of times so as to obtain a convergent value D_{c} of the present depth of discharge, and determine the remaining battery capacity of the battery device as indicated below:

Remaining_battery_capacity=1−D_{c} Eq. (12)

In some other embodiments of the invention, the method as illustrated in the first embodiment may also be combined into the second embodiment. For example, after updating the present depth of discharge D₃ as in Eq. (11), the controller 730 may derive an updated value V_{OCV3} of the open circuit voltage and an updated value R₃ of the resistance by looking up the first and second tables based on the present depth of discharge D₃. Next, the controller 730 may wait for a predetermined period of time, for example, T and measure a current closed circuit voltage V_{CCV} of the battery device 110. Next, the controller 730 may further update the amount of current and the present depth of discharge of the battery device as following:

I₃=(V_{OCV3}−V_{CCV})/R₃ Eq. (13)

CAR₄=I₃×T+CAR₃ Eq. (14)

D₄=CAR₄/Qmax Eq. (15)

After updating the present depth of discharge D₄ as in Eq. (15), the controller 730 may derive an updated value V_{OCV4} of the open circuit voltage and an updated value R₄ of the resistance by looking up the first and second tables based on the present depth of discharge D₄, and further update the amount of current and the present depth of discharge of the battery device in a similar manner as illustrated in Eq. (13)˜Eq. (15). The amount of current may converge after three or four times of updates.

Note that in some embodiments of the invention, the controller 730 may further process a plurality of values of the remaining battery capacity of the battery device determined during a period of time to obtain an accurate value as the remaining battery capacity of the battery device. For example, the controller 730 may calculate an average among the values determined during the period of time as the accurate value, or may further filter out some values diverging from the others before calculating the average so that the determined remaining battery capacity may be a more stable result.

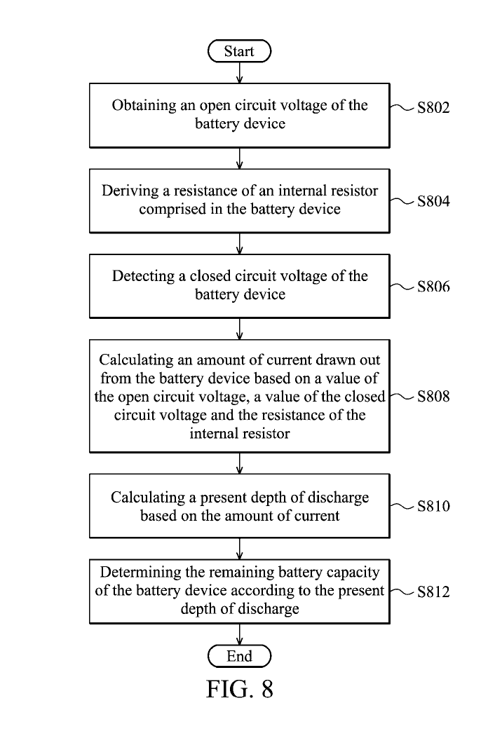

FIG. 8 is a flow chart showing a method for determining a remaining battery capacity of a battery device according to the second embodiment of the invention. To begin, an open circuit voltage of the battery device may be obtained (Step S802). As previously described, an initial voltage of the battery device may be detected right at the moment when the system 700 (or an electronic device comprising the system 700 and powered by the battery device 110) is started up and may be set as a value of an open circuit voltage of the battery device. Next, a resistance of an internal resistor comprised in the battery device may be derived (Step S804).

As illustrated above, the resistance of the internal resistor may be derived by looking up the first and second tables. Note that in some embodiments of the invention, the second table may be simplified by only comprising several values of the resistance versus several predefined values of the depth of discharge (DOD). Therefore, the resistance of the internal resistor may be derived simply by performing interpolation between two or more closest values. Note further that in some other embodiments of the invention, the second table may be omitted and the resistance of the internal resistor may be set as a fixed value regardless of the depth of discharge (DOD). Therefore, the resistance of the internal resistor may be derived simply based on the sensed temperature of the battery device. Note further that in still some other embodiments of the invention, the second table may be omitted and the resistance of the internal resistor may be set as a fixed value regardless of the depth of discharge (DOD) and the temperature. Therefore, the resistance of the internal resistor may be derived by directly obtaining the fixed value as the resistance of the internal resistor. Note further that in still some other embodiments of the invention, the resistance of the internal resistor or the resistance of the internal resistor in the second table may be updated anytime based on a current status of the electronic device. For example, the resistance of the internal resistor may be updated according to a charge/discharge voltage rise/drop and a charge/discharge current measured in a charge/discharge procedure of the battery device 110.

Next, a closed circuit voltage of the battery device may be detected by the detection circuitry 720 (Step S806). According to an embodiment of the invention, the detection circuitry 720 may wait for a predetermined period of time after the step S806 has been performed and then detect a voltage of the battery device as the closed circuit voltage. Next, an amount of current drawn out from the battery device may be calculated, as shown in Eq. (5), based on the value of the open circuit voltage, a value of the closed circuit voltage and the resistance of the internal resistor (Step S808). Next, a present depth of discharge may be calculated, as shown in Eq. (6) and Eq. (7), based on the amount of current (Step S810). Finally, the remaining battery capacity of the battery device may be determined, as shown in Eq. (8), according to the present depth of discharge (Step S812).

Note that in some embodiments of the invention, before performing the step S812, the resistance of the internal resistor and the value of the open circuit voltage may be updated based on the present depth of discharge obtained in Step S810, the amount of current drawn out from the battery device may also be updated based on the updated value of the open circuit voltage, a latest detected value of the closed circuit voltage and the resistance of the internal resistor as shown in Eq. (9), and the present depth of discharge may further be updated based on the updated amount of current as shown in Eq. (10) and (11). The of the closed circuit voltage may be repeatedly detected and the update of the resistance, the open circuit voltage, the amount of current and the present depth of discharge may be repeatedly performed for a predetermined number of times so as to obtain a convergent value of the present depth of discharge, which may be much closer to the actual present depth of discharge of the battery device. After obtaining the convergent value of the present depth of discharge, the remaining battery capacity of the battery device may be determined according to the convergent value of the present depth of discharge as shown in Eq. (12).

In still some embodiments of the invention, before performing the step S812, the resistance of the internal resistor and the value of the open circuit voltage may be updated based on the present depth of discharge obtained in Step S810, the amount of current drawn out from the battery device may also be updated based on the updated value of the open circuit voltage, a latest detected value of closed circuit voltage and the resistance of the internal resistor as shown in Eq. (13), and the present depth of discharge may further be updated based on the updated amount of current as shown in Eq. (14) and (15). The of the closed circuit voltage may be repeatedly detected and the update of the resistance, the open circuit voltage, the amount of current and the present depth of discharge may be repeatedly performed for a predetermined number of times so as to obtain a convergent value of the present depth of discharge, which may be much closer to the actual present depth of discharge of the battery device. After obtaining the convergent value of the present depth of discharge, the remaining battery capacity of the battery device may be determined according to the convergent value of the present depth of discharge as shown in Eq. (12).

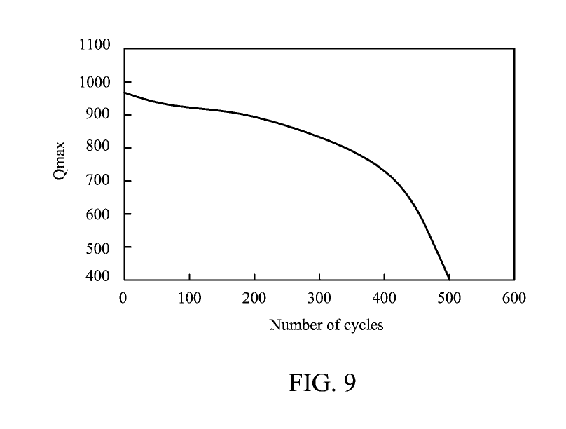

FIG. 9 is a schematic diagram showing a curve of the maximum battery capacity Qmax versus a number of charge/discharge cycles. As shown in FIG. 9, the maximum battery capacity of the battery device may be decreased or faded as the battery “age” increases. Note that the “age” of the battery device may refer to an amount of charge/discharge cycles to which the battery device has be subjected than to the actual amount of time that the battery has existed. Note further that the maximum battery capacity of the battery device may also be changed when the battery device is changed by an user.

In this regard, according to a third embodiment of the invention, the maximum battery capacity of the battery device Qmax, which may be required when deriving the present depth of discharge as shown in Eq. (7) and/or Eq. (11), may further be updated so as to provide accurate estimations for the depth of discharge, as well as the remaining run-time of the battery-powered electronic device. For example, a multiplication result of the amount of current I drawn out from the battery device 110, which may be measured via the external resistor R_{EXT} as shown in FIG. 1 in the first embodiment or may be derived as shown in Eq. (5) and Eq. (9) in the second embodiment, together with the time required for charging or discharging the battery from a first state to a second state may be utilized for estimating and updating the amount of maximum battery capacity of the battery device Qmax. In some embodiments of the invention, the first state may be designed as nearly 0% (or nearly 100%) remaining capacity and the second state may be designed as nearly 100% (or nearly 0%) remaining capacity. In other embodiments of the invention, the first state may be also designed as X % remaining capacity and the second state may be also designed as Y % remaining capacity, where |X−Y|<100.

Note that in the second embodiment of the invention, the Printed Circuit Board (PCB) area and the Bill of Materials (BOM) cost may be reduced as compared with the first embodiment of the invention since the hardware devices for measuring the amount current (such as the ADC 124 and the external resistor R_{EXT} as shown in FIG. 1) are no longer required. Therefore, the hardware cost of designing the system as shown in the second embodiment of the invention can be less than that in the first embodiment of the invention. In addition, although the amount current cannot be measured in the second embodiment of the invention via hardware devices, accurate estimations of the amount current, and further the remaining battery capacity, can still be achieved since the estimation results can be recursively updated until convergent values are obtained. Experiment result shows that the accuracy of the estimated remaining battery capacity obtained in the second embodiment approaches that obtained in the first embodiment, and both of them are much higher than that obtained from the conventional design.

The above-described embodiments of the present invention can be implemented in any of numerous ways. For example, the embodiments may be implemented using hardware, software or a combination thereof. It should be appreciated that any component or collection of components that perform the functions described above can be generically considered as one or more controllers that control the above discussed function. The one or more controllers can be implemented in numerous ways, such as with dedicated hardware, or with general purpose hardware that is programmed using microcode or software to perform the functions recited above.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A system for determining a remaining battery capacity of a battery device, wherein the battery device includes an internal resistor, comprising:
a detection circuitry, coupled to the battery device for detecting an open circuit voltage and a closed circuit voltage of the battery device; and
a controller, coupled to the detection circuitry,
wherein the controller calculates an amount of current drawn out from the battery device based on values of the open circuit voltage and the closed circuit voltage and a resistance of the internal resistor;
calculates a present depth of discharge based on the amount of current; and
determines the remaining battery capacity of the battery device according to the present depth of discharge.

2. The system as claimed in claim 1, wherein the detection circuitry comprises:
a temperature sensing device, coupled to the battery device for sensing a temperature of the battery device and generating a sensed voltage reflecting the temperature of the battery device at a sensing node;
a multiplexer, coupled to the sensing node and the detection node for receiving the sensed voltage and the closed circuit voltage, respectively, and multiplexing the sensed voltage and the closed circuit voltage; and
a first analog to digital converter, coupled to the multiplexer for receiving and analog to digital converting one of the sensed voltage and the closed circuit voltage outputted by the multiplexer, and outputting the one of the sensed voltage and the closed circuit voltage to the controller.

3. The system as claimed in claim 2, wherein the detection circuitry further detects an initial voltage of the battery device as the open circuit voltage, and the controller calculates the amount of current drawn out from the battery device by dividing a difference between the initial voltage and the closed circuit voltage into a resistance of the internal resistor comprised in the battery device.

4. The system as claimed in claim 3, wherein the controller obtains the resistance of the internal resistor according to a first table of the open circuit voltage versus a depth of discharge of the battery device and a second table of the resistance versus the depth of discharge based on a value of the initial voltage of the battery device.

5. The system as claimed in claim 4, wherein the controller further updates the resistance by looking up the first table and the second table based on the present depth of discharge.

6. The system as claimed in claim 5, wherein the controller further updates the amount of current by dividing a difference between the open circuit voltage and the closed circuit voltage into the resistance.

7. The system as claimed in claim 6, wherein the controller further repeatedly updates a value of the open circuit voltage, the resistance and the amount of current for a predetermined number of times to obtain a convergent value of the present depth of discharge, and determines the remaining battery capacity of the battery device according to the convergent value of the present depth of discharge.

8. The system as claimed in claim 4, wherein the controller further obtains the first table and the second table based on the sensed voltage reflecting the temperature of the battery device.

9. The system as claimed in claim 4, wherein the controller further updates the second resistance of the internal resistor in the second table according to a charge/discharge voltage rise/drop and a charge/discharge current of the battery device.

10. The system as claimed in claim 1, wherein the controller further processes a plurality of values of the remaining battery capacity of the battery device determined during a period of time to obtain an accurate value as the remaining battery capacity of the battery device.

11. A method for determining a remaining battery capacity of a battery device, comprising:
(a) obtaining an open circuit voltage of the battery device;
(b) deriving a resistance of an internal resistor comprised in the battery device;
(c) detecting a closed circuit voltage of the battery device;
(d) calculating an amount of current drawn out from the battery device based on a value of the open circuit voltage, a value of the closed circuit voltage and the resistance of the internal resistor;
(e) calculating a present depth of discharge based on the amount of current; and
(f) determining the remaining battery capacity of the battery device according to the present depth of discharge.

12. The method as claimed in claim 11, further comprising:
(g) updating the resistance of the internal resistor and the value of the open circuit voltage based on the present depth of discharge;
(h) updating the amount of current drawn out from the battery device based on the value of the open circuit voltage and the resistance of the internal resistor updated in step (g) and the value of the closed circuit voltage; and
(i) calculating the present depth of discharge based on the amount of current, wherein the steps (g), (h) and (i) are performed before the step (0.

13. The method as claimed in claim 12, wherein the steps (g), (h) and (i) are repeatedly performed for a predetermined number of times before performing the step (f) to obtain a convergent value of the present depth of discharge, and wherein the remaining battery capacity of the battery device is determined according to the convergent value of the present depth of discharge.

14. The method as claimed in claim 11, wherein the resistance of the internal resistor is derived by looking up a first table of the open circuit voltage versus a depth of discharge of the battery device and a second table of the resistance of the internal resistor versus the depth of discharge of the battery device.

15. The method as claimed in claim 11, wherein the step (b) further comprises:
(b-1) detecting a temperature of the battery device;
(b-2) obtaining a first table of the open circuit voltage versus a depth of discharge of the battery device and a second table of the resistance of the internal resistor versus the depth of discharge of the battery device according to the temperature of the battery device; and
(b-3) looking up the first table by using the value of the open circuit voltage to obtain a derived depth of discharge and looking up the second table by using the derived depth of discharge to obtain the resistance of the internal resistor.

16. The method as claimed in claim 11, wherein the step (c) further comprises:
(c-1) waiting for a predetermined period of time after the step (a) has been performed; and
(c-2) detecting a voltage of the battery device as the closed circuit voltage.

17. The method as claimed in claim 11, wherein the resistance obtained in step (b) is updated according to a charge/discharge voltage rise/drop and a charge/discharge current of the battery device.

18. The method as claimed in claim 11, the step (f) further comprises:
(f-1) processing a plurality of values of the remaining battery capacity of the battery device determined during a period of time to obtain an accurate value as the remaining battery capacity of the battery device.
